(19) United States
(12) Patent Application Publication
(10) Pub. No.: US 2005/0127399 A1
(43) Pub. Date: Jun. 16, 2005

(54) Non-uniform gate pitch semiconductor devices

(76) Inventor: Ronald C. Meadows, Youngsville, NC (US)

Correspondence Address: MYERS BIGEL SIBLEY & SAJOVEC, PO BOX 37428, RALEIGH, NC, 27627, US

(21) Appl. No.: 10/734,398

(22) Filed: Dec. 12, 2003

(51) Int. Cl. H01L 31/072

(52) U.S. Cl. 257/194

(57) ABSTRACT

Semiconductor devices having a plurality of unit cells connected in parallel are provided. The unit cells each have a gate finger with a gate pitch between adjacent ones of the gate fingers. The gate pitch is non-uniform in a predetermined pattern.

### FIELD OF THE INVENTION

The present invention relates microelectronic devices and more particularly to high power semiconductor devices.

### BACKGROUND OF THE INVENTION

Electrical circuits requiring high power handling capability (>20 watts) while operating at high frequencies such as radio frequencies (500 MHz), S-band (3 GHz) and X-band (10 GHz) have in recent years become more prevalent. Because of the increase in high power, high frequency circuits there has been a corresponding increase in demand for transistors which are capable of reliably operating at radio frequencies and above while still being capable of handling higher power loads.

To provide increased power handling capabilities, transistors with a larger effective area have been developed. However, as the area of a transistor increases, the transistor may become less suitable for high frequency operations which, typically, require a small source to drain distance so that the carrier transit times are limited. One technique for increasing the area of a transistor while still providing for high frequency operations is to use a plurality of transistor cells that are connected in parallel. Such a configuration includes a plurality of elongated gate “fingers” which control the flow of current through each of the plurality of unit cells. Thus, the source to drain distance of each cell may be kept relatively small while still providing a transistor with increased power handling capability. Conventionally, when a plurality of parallel transistor cells are connected in parallel on a single chip, the cells are evenly spaced such that the gate-to-gate distance between adjacent cells (referred to herein as “pitch” or “gate pitch”) is uniform from one cell to the next.

When such multi-cell transistors are used in high frequency operations, they may generate a large amount of heat. As a device heats up, performance of the device typically degrades. Such degradation may be seen in gain, linearity and/or reliability. Thus, efforts have been made to keep junction temperatures of the transistors below a peak operating temperature. Typically, heatsinks and/or fans have been used to keep the devices cool so as to ensure proper function and reliability. However, cooling systems may be increase size, electrical consumption, manufacturing costs and/or operating costs of systems employing such transistors.

With uniform pitch multi-cell transistors, the operating temperature of cells near the center of the array is typically greater than that of the cells at the periphery. This is generally the case because the cells at the periphery have a greater thermal gradient to areas surrounding the cells. Thus, for example, adjacent cells near the center of the multi-cell array will each generate heat and thus, each side of the cells will be at an elevated temperature with respect to cells farther from the center. This results in a thermal profile that is roughly a bell curve with center junction temperatures being the hottest and with the outer most junctions having a substantially reduced operating temperature compared to the center junctions.

An uneven temperature distribution among the junctions of a device may reduce device linearity. For example, for a device with a plurality of evenly spaced gate fingers connected by a manifold, RF phasing errors may occur along both the gate manifold and the individual gate fingers as a result of differing gate resistance as a function of temperature. Conventionally, to address these issues the spacing between the gate fingers is widened and/or the length of the fingers are shortened and additional fingers added to achieve the same net active area. Both of these solutions result in spreading the heat load generated in the center of the device over a wider area. These solutions also result in a larger area for the multi-cell transistor that may reduce the number of die per wafer.

### SUMMARY OF THE INVENTION

Embodiments of the present invention provide a semiconductor device having a plurality of unit cells connected in parallel. The unit cells each have a gate finger with a gate pitch between adjacent ones of the gate fingers. The gate pitch is non-uniform in a predetermined pattern.

In particular embodiments of the present invention, the predetermined pattern of non-uniform pitch between the gate fingers provides a substantially uniform junction temperature to a substantial majority of the gate fingers when in operation. The predetermined pattern of non-uniform pitch between the gate fingers may also provide a lower peak junction temperature than a corresponding uniform gate pitch device for a particular set of operating conditions. The predetermined pattern of non-uniform pitch between the gate fingers may provide a substantially uniform junction temperature to all but the outermost gate fingers of the device when in operation.

In certain embodiments of the present invention, the unit cells are a plurality of unit cells arranged in a linear array. In other embodiments of the present invention, the unit cells include a plurality of unit cells arranged in a two dimensional array and the non-uniform pitch gate fingers are provided in at least one of the two dimensions of the two dimensional array. The non-uniform pitch gate fingers may also be provided in both dimensions of the two dimensions of the two dimensional array.

In still further embodiments of the present invention, the pitch between that gate fingers is inversely related to a distance of the gate finger from a center of the device. The pitch between the gate fingers at a periphery of the device may be less than the pitch between gate fingers at a center of the device.

In particular embodiments of the present invention, the unit cells are MESFET or HEMT unit cells. The unit cells may also be silicon carbide or gallium nitride semiconductor device unit cells.

In still other embodiments of the present invention, a field effect transistor includes a plurality of unit cells electrically connected in parallel, each unit cell having a source region and a drain region. A plurality of gates of the unit cells are also provided. The plurality of gates are electrically connected in parallel and have a non-uniform spacing between the gates. The non-uniform spacing between the gates may be provided in a pattern that provides a lower peak junction temperature than a corresponding uniform gate pitch device for a particular set of operating conditions. Additionally or alternatively, the non-uniform spacing between the gates may be provided in a pattern that provides a lower variation in junction temperature than a corresponding uniform gate pitch device for a particular set of operating conditions.

In particular embodiments of the present invention, the plurality of unit cells of the transistor comprise a linear array of unit cells. The plurality of unit cells of the transistor could also be a two dimensional array of unit cells. In such a case, the non-uniform spacing of the gates may be in a single or both dimensions of the two dimensional array. The plurality of unit cells may also be a plurality of silicon carbide unit cells or gallium nitride unit cells.

In yet other embodiments of the present invention, a peak junction temperature in a semiconductor device having a plurality of gates electrically connected in parallel may be reduced by varying the spacing between the gates of the semiconductor device. The spacing between the gates may be varied such that gates in a central region of the device are spaced farther apart from adjacent gates than are gates in a peripheral region of the device. The spacing between the gates could be varied linearly with distance from a central region of the device. The spacing between the gates could also vary non-linearly with distance from a central region of the device.

### DESCRIPTION OF THE DRAWINGS

The advantages and features of the invention, and the manner in which the same are accomplished, will become more readily apparent upon consideration of the following detailed description of the invention taken in conjunction with the accompanying drawings, which illustrate exemplary embodiments, and wherein:

FIG. 1 is a cross-sectional view of a portion of a multi-cell transistor according to embodiments of the present invention;

FIG. 2 is a plan view of a portion of a multi-cell transistor according to embodiments of the present invention;

FIG. 3 is a graph of a simulated thermal profile of a conventional uniform gate pitch device and a non-uniform gate pitch device according to embodiments of the present invention;

FIG. 4 is a graph of a RF performance of a conventional uniform gate pitch device and a non-uniform gate pitch device according to embodiments of the present invention;

FIG. 5A is a thermal profile of a RF performance of a conventional uniform gate pitch device;

FIG. 5B is a thermal profile of a non-uniform gate pitch device according to embodiments of the present invention;

FIG. 6A is a top view thermal image of a conventional uniform gate pitch device; and

FIG. 6B is a top view thermal image of a non-uniform gate pitch device according to embodiments of the present invention.

### DETAILED DESCRIPTION

The present invention will now be described with reference to the Figures that illustrate various embodiment of the present invention. As illustrated in the Figures, the sizes of layers or regions are exaggerated for illustrative purposes and, thus, are provided to illustrate the general structures or the present invention. Furthermore, various aspects of the present invention are described with reference to a layer being formed on a substrate or other layer. As will be appreciated by those of skill in the art, references to a layer being formed on another layer or substrate contemplates that additional layers may intervene. References to a layer being formed on another layer or substrate without an intervening layer are described herein as being “directly” on the layer or substrate. Like numbers refer to like elements throughout.

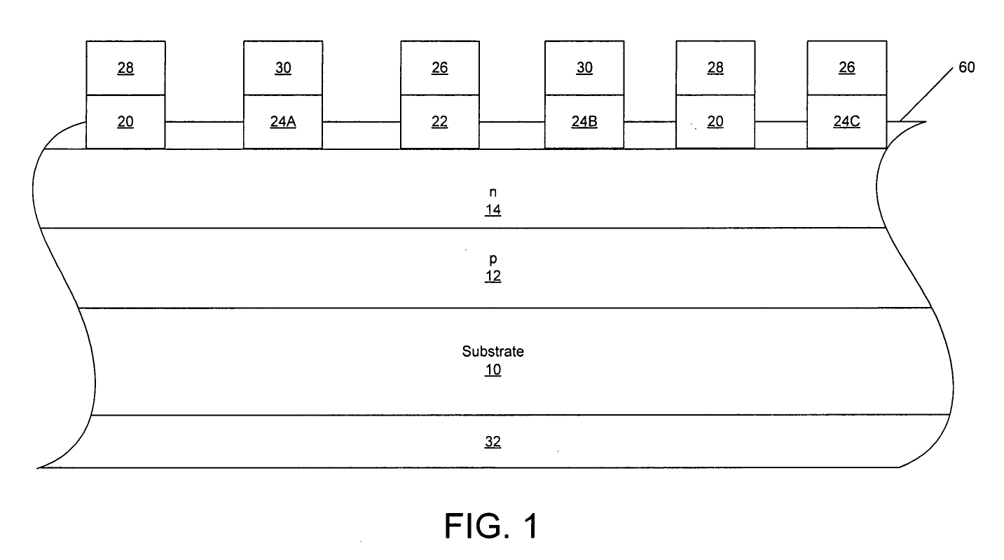

FIG. 1 illustrates a portion of an exemplary transistor according to embodiments of the present invention. While embodiments of the present invention are illustrated with reference to a SiC Metal Semiconductor Field Effect Transistor (MESFET), the present invention should not be construed as limited to such devices. Thus, embodiments of the present invention may include other transistor devices having a plurality of unit cells, such as Bipolar Junction Transistors (BJTs). Thus, while embodiments of the present invention are discussed with reference to a non-uniform gate pitch, references to a “gate” herein refer to a controlling electrode of a semiconductor device which may, for example, be the base electrode of a BJT. Embodiments of the present invention may be suitable for use in any semiconductor device where a more/relatively uniform junction temperature is desired and multiple unit cells of the device are present. Thus, for example, embodiments of the present invention may be suitable for use in non-silicon carbide devices, such as GaN, GaAs and/or Si devices.

As illustrated in FIG. 1, an exemplary portion of a MESFET incorporating embodiments of the present invention may include a first epitaxial layer 12 of p-type conductivity is grown on a single crystal bulk silicon carbide substrate 10 of either p-type or n-type conductivity or semi-insulating. The first epitaxial layer of silicon carbide 12 is disposed between the substrate 10 and an n-type epitaxial layer 14. An optional metallization layer 32 may be formed on the opposite side of the substrate from the first epitaxial layer 12.

The first epitaxial layer 12 may be a p-type conductivity silicon carbide epitaxial layer, an undoped silicon carbide epitaxial layer or a very low doped n-type conductivity silicon carbide epitaxial layer. If a low doped silicon carbide epitaxial layer is utilized, then in certain embodiments, the doping concentration of the first epitaxial layer 12 is less than about 5×10¹⁵ cm⁻³. If an undoped or n-type first epitaxial layer 12 is utilized, then in certain embodiments, the substrate 10 is a semi-insulating silicon carbide substrate. If an undoped or n-type first epitaxial layer 12 is utilized, a high quality channel layer may be formed without the buffer layer having any significant electrical effect on the transistor.

Ohmic contacts 20 and 22 may be formed on the second epitaxial layer 14 and are spaced apart so as to provide a source contacts 20 and a drain contacts 22. A series of Schottky gate contacts 24A, 24B and 24C, also referred to as gate fingers, are formed on the second epitaxial layer 14 between the source contacts 20 and the drain contacts 22. As illustrated, optional metal overlayers 26, 28 and 30 are formed on the source and drain contacts 20 and 22 and the Schottky gate contacts 24A, 24B and 24C. A passivation layer 60 may also be provided. As illustrated in FIG. 1, certain embodiments of the present invention provide a linear array of cells that are connected in parallel. Thus, the gate contacts 24A, 24B and 24C may be connected in parallel in a third dimension. In still other embodiments of the present invention a two dimensional array of cells may be provided.

While three gate fingers 24A, 24B and 24C are illustrated in FIG. 1, other numbers of gate fingers may be utilized. Furthermore, other MESFET or semiconductor device configurations may also be utilized. For example, devices such as those described in U.S. Pat. Nos. 4,762,806; 4,757,028, 5,270,554; and 5,925,895, the disclosures of which are incorporated herein as if set forth fully, may be utilized in embodiments of the present invention. Also devices such as those described in commonly assigned U.S. patent application Ser. No. 09/567,717, filed on May 10, 2000 entitled “SILICON CARBIDE METAL-SEMICONDUCTOR FIELD EFFECT TRANSISTORS AND METHODS OF FABRICATING SILICON CARBIDE METAL-SEMICONDUCTOR FIELD EFFECT TRANSISTORS”; Ser. No. 10/136,456, filed Oct. 24, 2001 entitled “DELTA DOPED SILICON CARBIDE METAL-SEMICONDUCTOR FIELD EFFECT TRANSISTORS AND METHODS OF FABRICATING DELTA DOPED SILICON CARBIDE METAL-SEMICONDUCTOR FIELD EFFECT TRANSISTORS HAVING A GATE DISPOSED IN A DOUBLE RECESS STRUCTURE”; and Ser. No. 10/304,272, filed Nov. 26, 2002 entitled “TRANSISTORS HAVING BURIED P-TYPE LAYERS BENEATH THE SOURCE REGION AND METHODS OF FABRICATING THE SAME,” the disclosures of which are incorporated herein as if set forth fully, may be utilized in embodiments of the present invention. However, embodiments of the present invention are not limited to MESFETs but may be utilized with other devices having an array of controlling electrodes and, in certain embodiments, a linear array of controlling electrodes.

As is further seen in FIG. 1, the gate fingers 24A, 24B and 24C are non-uniformly spaced. In particular, the gate fingers 24A, 24B and 24C are spaced apart in a predefined manner rather than merely being spaced differing distances as a result of variation in manufacturing. The predefined pattern may provide a lower peak junction temperature in the device that includes the gate fingers 24A, 24B and 24C. The predefined pattern may be determined, for example, experimentally using thermal modeling of a device and/or through trial and error. The predefined pattern may be a linear or non-linear variation in spacing. Furthermore, some portions of the gate fingers may be uniformly spaced while others are non-uniformly spaced. Thus, a non-uniform gate pitch refers to at least one pitch between gate fingers being different from the pitch between other gate fingers. In certain embodiments of the present invention, the predefined pattern is selected such that a substantially uniform junction temperature is provided for a substantial majority of the gate fingers of a device. In further embodiments of the present invention the predefined pattern provides a substantially uniform junction temperature for all but the outermost gate fingers. In still further embodiments of the present invention, the predefined pattern provides a substantially uniform junction temperature for all of the gate fingers. A substantially uniform junction temperature as used herein refers to a junction temperature that does not differ by more than about 5° C. In certain embodiments of the present invention, the junction temperature may not differ by more than about 5° C. over 80% or more of the unit cells that comprise the device. In certain embodiments of the present invention, the junction temperature may not differ by more than about 5° C. over 95% or more of the unit cells that comprise the device.

As discussed above, embodiments of the present invention may provide a linear (single dimension) array of cells having a non-uniform gate pitch of a predefined pattern. Embodiments of the present invention may also provide a two dimensional array of cells having a non-uniform gate pitch. In embodiments of the present invention where a two dimensional array of cells is provided, the variation in gate pitch may be in one or both of the dimensions. Thus, embodiments of the present invention should not be construed as limited to linear arrays of cells.

In particular embodiments of the present invention, a high power thermally balanced semiconductor device is provided. The semiconductor device includes a plurality of like elemental semiconductor devices. The elemental semiconductor devices have first and second current conducting terminals and a control terminal. The elemental semiconductor devices are aligned side-by-side in a common semiconductor chip. The control terminals are connected in parallel and individually spaced so that the mutual separation between immediately adjacent control terminals is varied in a predetermined manner from a central region of the semiconductor chip to opposing outer end regions thereof.

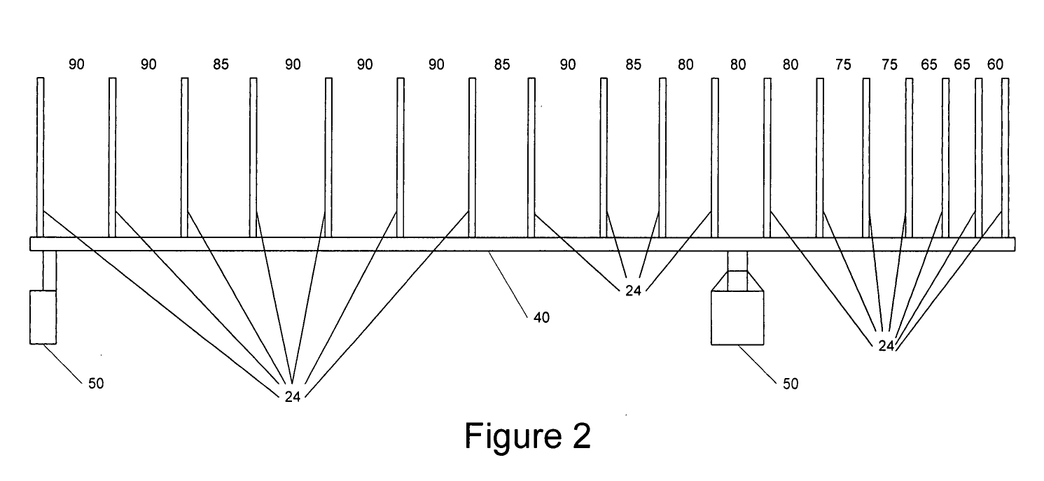

FIG. 2 is a top plan view of one half of a gate structure of a device according to certain embodiments of the present invention. The device may be a SiC MESFET as is illustrated in FIG. 1. In FIG. 2, the gate fingers 24 are mirrored about the left vertical axis of the figure so as to provide a complete device having a plurality of cells, each cell having its own gate finger. The spacing between the gate fingers 24 is indicated between the corresponding gate fingers and is in μm. Thus, for example, the two leftmost gate fingers illustrated have a spacing of 90 μm and the two rightmost gate fingers have a spacing of 60 μm. An electrically conductive manifold 40 is provided to connect the gate fingers 24 in parallel. Contact pads 50 are also provided in electrical connection with the manifold 40.

As is seen in FIG. 2, the pitch between the gate fingers 24 varies from a small pitch to a larger pitch toward the center of the device. By increasing the pitch at the center of the device, the increased heat dissipation area may compensate for the decreased thermal gradient at the center of the device such that the junction temperature associated with the respective gate fingers may be moderated. A more uniform junction temperature may provided for a decreased peak junction temperature which may result in improved reliability over a conventional uniform spaced device under the same operating conditions. Furthermore, the more uniform thermal profile may reduce impedance differences between the fingers and, thereby, improve linearity of an RF device.

### EXAMPLES

The following examples are illustrative of certain embodiments of the present invention and shall not be construed as limiting the present invention.

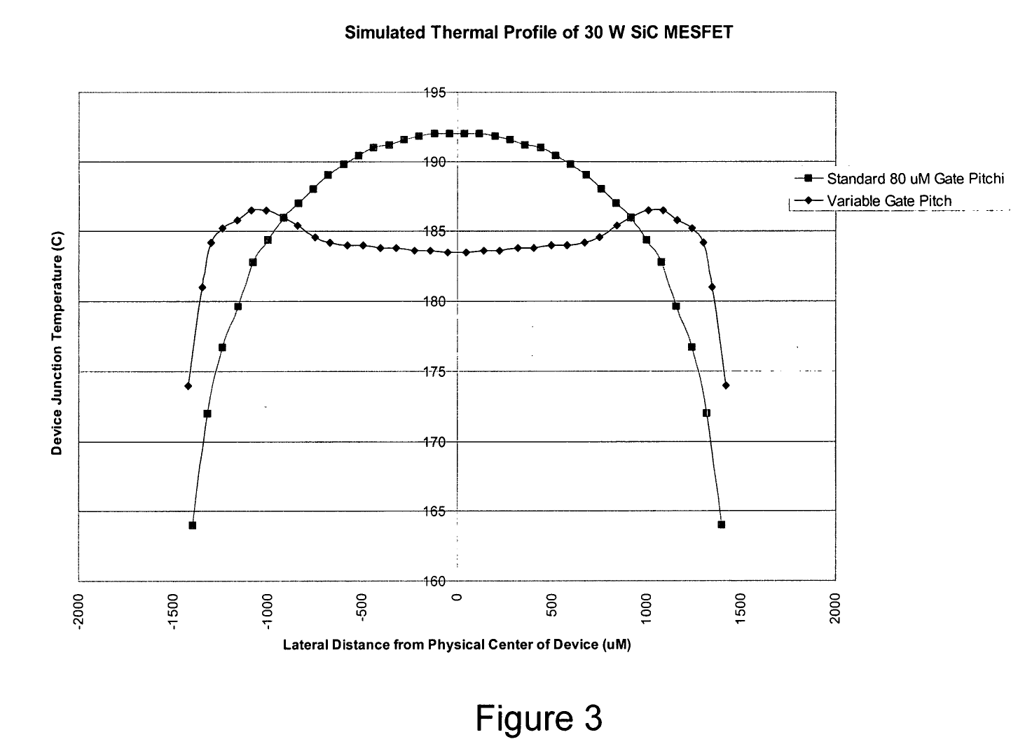

SiC MESFETs having the gate structure illustrated in FIG. 2 and a devices having a uniform 80 μm gate pitch were fabricated and packaged. Each of the devices was a 30 W device. The devices were simulated using Harvard Thermal, Inc., TAS thermal modeling software. The predicted results are shown in FIG. 3. As seen in FIG. 3, the non-uniform gate pitch device would be expected to have a more uniform temperature profile in the gate area of the device.

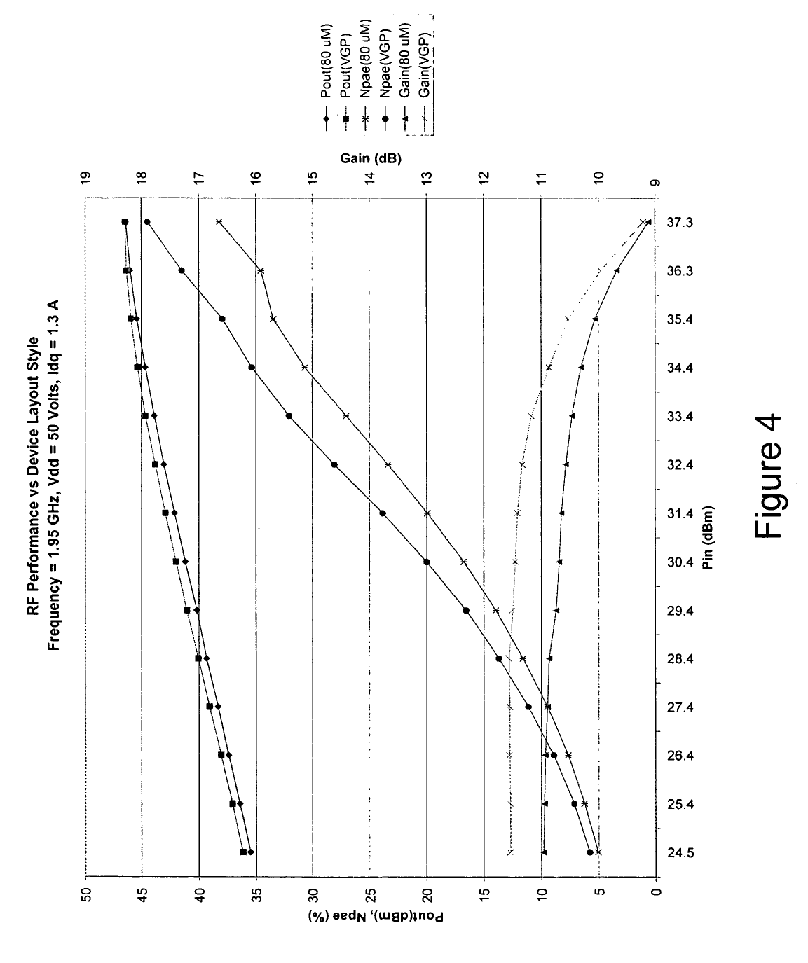

The fabricated devices were also measured for RF performance. FIG. 4 shows the typical RF performance from the devices. As seen in FIG. 4, the non-uniform gate pitch device performed better than the uniform gate pitch device. An increase in gain of about 0.5 dB and an increase in output power of about 0.5 dBm were observed.

No thermal scans were performed on the 30 W devices, however, if a typical number of 0.02 dB×C/W derating value for increasing device temperature then the junction temperatures of the non-uniform gate pitch FET's would appear to be running about 25° C. cooler than the uniform gate pitch FET's.

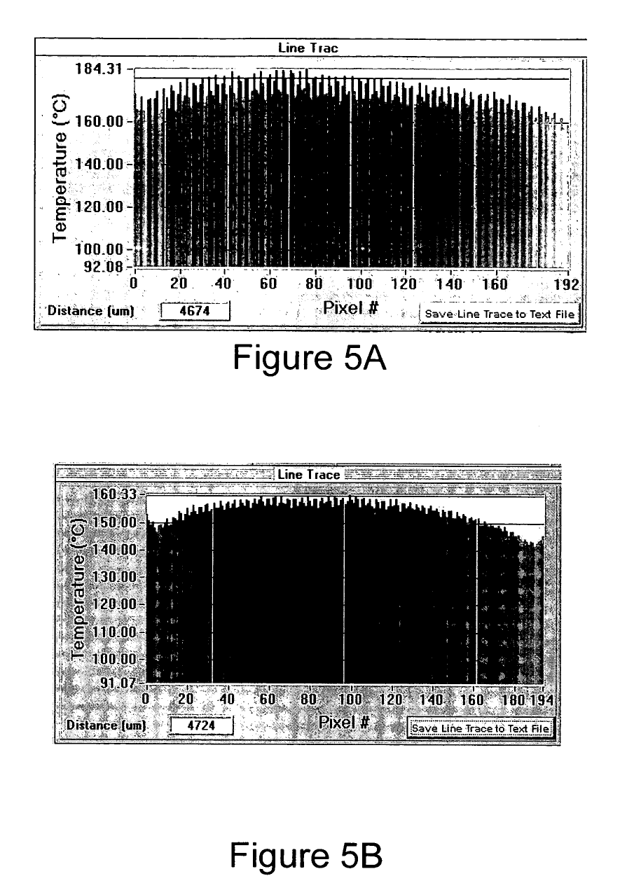

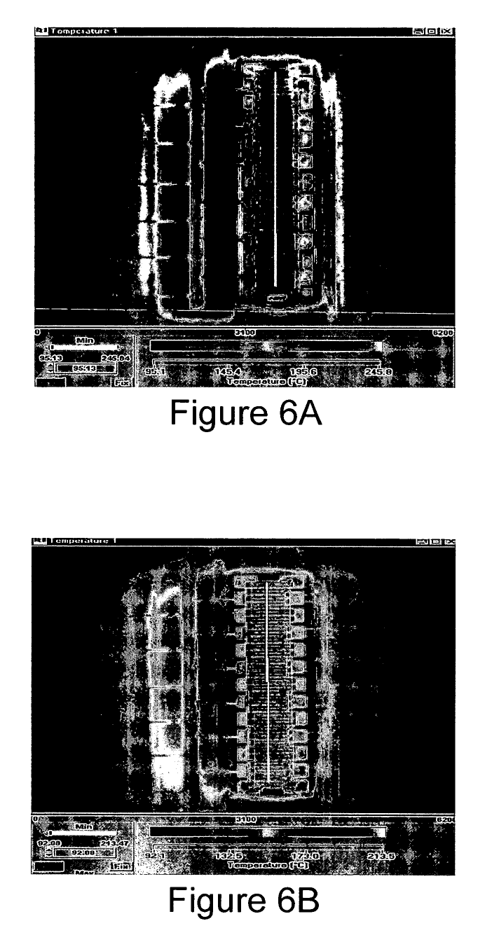

In addition to the 30 W FETs, 60 W FET's were also fabricated and packaged. The 60 W FETs included uniform gate pitch devices having an 80 μm gate pitch and non-uniform gate pitch devices. The non-uniform gate pitch devices start with a 92 μm pitch for the center fingers then do a pseudo linear reduction outward for most of the FET. The outermost fingers are then tightly spaced. Thus, for half the device, gate pitches of 92, 92, 88, 88, 86, 86, 86, 84, 84, 84, 84, 84, 84, 82, 82, 82, 82, 80, 82, 82, 82, 80, 78, 72, 60, 50 and 40 μm were utilized. Measurements were taken with a base plate temperature of 90° C. with Vdd=50 volts and Idq=1.8 A. FIGS. 5A and 5B are thermal profiles for the uniform gate pitch device, FIG. 5A and the non-uniform gate pitch device, FIG. 5B. As seen in FIGS. 5A and 5B, the non-uniform gate pitch device runs approximately 25° C. cooler than the uniform gate pitch device. FIGS. 6A and 6B are top view thermal profiles for the uniform gate pitch device, FIG. 6A and the non-uniform gate pitch device, FIG. 6B. RF characterization for the 60 W devices showed comparable performance enhancements as were found in the 30 W devices.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device comprising:
a plurality of unit cells connected in parallel, the unit cells each having a gate finger, wherein a pitch between the gate fingers is varied in a predetermined pattern between the gate fingers so as to provide a non-uniform pitch between the gate fingers.

2. The semiconductor device of claim 1, wherein the predetermined pattern of non-uniform pitch between the gate fingers provides a substantially uniform junction temperature to a substantial majority of the gate fingers when in operation.

3. The semiconductor device of claim 1, wherein the predetermined pattern of non-uniform pitch between the gate fingers provides a lower peak junction temperature than a corresponding uniform gate pitch device for a particular set of operating conditions.

4. The semiconductor device of claim 1, wherein the predetermined pattern of non-uniform pitch between the gate fingers provides a substantially uniform junction temperature to all but the outermost gate fingers of the device when in operation.

5. The semiconductor device of claim 1, wherein the unit cells comprise a plurality of unit cells arranged in a linear array.

6. The semiconductor device of claim 1, wherein the unit cells comprise a plurality of unit cells arrange in a two dimensional array and wherein the non-uniform pitch gate fingers are provided in at least one of the two dimensions of the two dimensional array.

7. The semiconductor device of claim 6, wherein the non-uniform pitch gate fingers are provided in both dimensions of the two dimensions of the two dimensional array.

8. The semiconductor device of claim 1, wherein the pitch between that gate fingers is inversely proportional to a distance of the gate finger from a center of the device.

9. Canceled

10. The semiconductor device of claim 1, wherein the unit cells comprise MESFET unit cells.

11. The semiconductor device of claim 1, wherein the unit cells comprise silicon carbide semiconductor device unit cells or gallium nitride semiconductor device unit cells.

12. The semiconductor device of claim 1, wherein the predetermined pattern of non-uniform pitch between the gate fingers provides a more uniform junction temperature than a corresponding uniform gate pitch device for a particular set of operating conditions.

13. The semiconductor device of claim 2, wherein the junction temperature does not differ by more than about 5° C. over at least 80% of the plurality of unit cells.

14. The semiconductor device of claim 2, wherein the junction temperature does not differ by more than about 5° C. over at least 95% of the plurality of unit cells.

15. A field effect transistor, comprising:
a plurality of unit cells electrically connected in parallel, each unit cell having a source region and a drain region; and
a plurality of gates of the unit cells, the plurality of gates being electrically connected in parallel and having a non-uniform spacing between the gates, wherein the non-uniform spacing between the gates is provided in a pattern that provides a lower peak junction temperature than a corresponding uniform gate pitch device for a particular set of operating conditions.

16. The field effect transistor of claim 15, wherein the plurality of unit cells comprise a linear array of unit cells.

17. The field effect transistor of claim 15, wherein the plurality of unit cells comprise a two dimensional array of unit cells.

18. The field effect transistor of claim 17, wherein the non-uniform spacing of the gates is in a single dimension of the two dimensional array.

19. The field effect transistor of claim 17, wherein the non-uniform spacing of the gates is in both dimensions of the two dimensional array.

20. The field effect transistor of claim 15, wherein the plurality of unit cells comprise a plurality of silicon carbide unit cells.

21. A method of controlling a peak junction temperature in a semiconductor device having a plurality of gates electrically connected in parallel, the method comprising varying a spacing between the gates.

22. The method of claim 21, wherein the step of varying a spacing between the gates comprises varying the spacing between the gates such that gates in a central region of the device are spaced farther apart from adjacent gates than are gates in a peripheral region of the device.

23. The method of claim 21, wherein the step of varying a spacing between the gates comprises varying the spacing between the gates linearly with distance from a central region of the device.

24. The method of claim 21, wherein the step of varying a spacing between the gates comprises varying the spacing between the gates non-linearly with distance from a central region of the device.

25. A semiconductor device comprising:
a plurality of unit cells connected in parallel, the unit cells each having a gate finger; and
means for providing a substantially uniform junction temperature to a substantial majority of the gate fingers when in operation.

26. The semiconductor device of claim 25, wherein the means for providing provides a junction temperature does not differ by more than about 5° C. over at least 80% of the plurality of unit cells.

27. The semiconductor device of claim 25, wherein the means for providing provides a junction temperature does not differ by more than about 5° C. over at least 95% of the plurality of unit cells.
